(19) United States
(12) Patent Application Publication
(10) Pub. No.: US 2009/0009744 A1
(43) Pub. Date: Jan. 8, 2009

(54) ILLUMINATION SYSTEM FOR A MICROLITHOGRAPHIC PROJECTION EXPOSURE APPARATUS

(75) Inventor: Damian Fiolka, Oberkochen (DE)

Correspondence Address: FISH & RICHARDSON PC, P.O. BOX 1022, MINNEAPOLIS, MN, 55440-1022, US

(73) Assignee: CARL ZEISS SMT AG, Oberkochen (DE)

(21) Appl. No.: 11/814,929

(22) PCT Filed: Feb. 8, 2005
(86) PCT No.: PCT/EP05/01224

§ 371 Date: Sep. 17, 2008

(51) Int. Cl. G03F 7/20

(52) U.S. Cl. 355/67

(57) ABSTRACT

An illumination system for a microlithographic projection exposure apparatus (10) comprises an optical axis (28), a pupil plane (74) and a diffractive optical element (76; 76b) as a field defining element. The diffractive optical element (76, 76b) is positioned at least approximately in the pupil plane (74) and extends in an element plane (94) whose normal (96) is inclined with respect to the optical axis (28) by a tilt angle α 0°. Rotating the diffractive optical element deforms the illuminated field (14). For example, if the diffractive optical element (76; 76b) is configured such that it produces a rectangular light field (14′) for α=0°, rotating the diffractive optical element (76; 76b) around an axis of rotation (80) that is perpendicular both to the optical axis (28) and the scan direction (Y) results in an illuminated field (14) having the shape of a ring segment.

### BACKGROUND OF THE INVENTION

1. Field of the Invention

The invention relates generally to illumination systems for microlithographic projection exposure apparatuses. More particularly, the invention relates to illumination systems that allow to illuminate a curved region on the mask, and particularly a region having the shape of a ring segment.

2. Description of Related Art

Microlithography (also called photolithography) is a technology for the fabrication of integrated circuits, liquid crystal displays and other microstructured devices. More particularly, the process of microlithography, in conjunction with the process of etching, is used to pattern features in thin film stacks that have been formed on a substrate, for example a silicon wafer. At each layer of the fabrication, the wafer is first coated with a photoresist which is a material that is sensitive to radiation, such as deep ultraviolet (DUV) light. Next, the wafer with the photoresist on top is exposed to projection light through a mask in a projection exposure apparatus. The mask contains a circuit pattern to be projected onto the photoresist. After exposure the photoresist is developed to produce an image corresponding to the circuit pattern contained in the mask. Then an etch process transfers the circuit pattern into the thin film stacks on the wafer. Finally, the photoresist is removed.

A projection exposure apparatus typically includes an illumination system, a mask alignment stage, a projection lens and a wafer alignment stage. The illumination system illuminates a region of the mask that is to be projected onto the photoresist.

The optimum shape of this region depends on the type of projection exposure apparatus and particularly on the projection lens. In apparatuses in which the mask and the photoresist rest during the exposure, as is the case in apparatuses usually referred to as “steppers”, the shape of the illuminated field is usually adapted to the geometry of the microstructured device. More widely used are apparatuses in which the wafer and the mask are moved during the exposure. With these apparatuses that are generally referred to as “scanners” because the illuminated field scans over the mask, the illuminated field has the shape of a slit. The lateral short sides of the slit extending along the scan direction are usually defined by parallel straight lines. The longer sides of the slit may be defined by straight or curved lines. In the latter case the illuminated field has, at least approximately, the shape of a ring segment.

The shape of a ring segment is sometimes required by projection lenses having intricated beam pathes, for example certain lenses containing truncated imaging mirrors. An illumination system that may be used with different projection lenses should therefore be configured such that the shape of the illuminated field can be quickly varied.

For directing light produced by a light source onto the region on the mask to be illuminated, conventional illumination systems usually contain a field defining element. This field defining element is generally an optical raster element, for example a diffractive optical element or a refractive optical element such as an array of micro-lenses. The field defining element is arranged in or in close proximity to a pupil plane of the illumination system. By selectively diverting light rays impinging on the field defining element it is possible, at least to a good approximation, to achieve the desired intensity distribution in the mask plane. An additional field stop arranged in a field plane ensures sharp edges of the illuminated field, at least (in the case of scanners) for the short lateral sides of the illuminated field. The better the field defining element directs the light rays onto the desired region, the less light is lost at the field stop.

However, although it is fairly simple to achieve a rectangular illuminated field with a field defining element, more complicated shapes, for example the shape of ring segments, can until now only be achieved by illuminating an appropriately shaped field stop with a rectangular shaped light field. This results in considerable light losses at the field stop. The light absorbed by the field stop increases its temperature, and this may cause several problems, for example deformations of the field stops. Such deformations may cause changes of the geometry of the illuminated during the operation of the projection exposure apparatus.

### SUMMARY OF THE INVENTION

It is an object of the present invention to provide an illumination system of a microlithographic exposure system having an improved field defining element.

It is a further object of the present invention to provide an illumination system having a field defining element that allows to produce also more complicated light intensity distributions in the mask plane.

It is a still further object of the present invention to provide an illumination system that allows to efficiently produce an illuminated field that has the shape of a ring segment.

This and other objects are achieved by an illumination system for microlithographic projection exposure apparatus that comprises an optical axis, a pupil plane and a diffractive optical element. The diffractive optical element is positioned at least approximately in the pupil plane and extends in an element plane whose normal is inclined with respect to the optical axis by a tilt angle α≠0°.

The invention is based on the discovery that rotating a diffractive optical element, which is substantially arranged in a pupil plane, around an axis of rotation that is not parallel to the optical axis, alters the shape of the illuminated-field in the mask plane. More particularly, such a rotation locally varies the divergence produced by the diffractive optical element in a direction that is perpendicular to the axis of rotation. These local variations of the divergence result in deformations or distortions of the original shape. The original shape is considered to be the shape that would be obtained with a tilt angle α≠0°, i.e. the intensity distribution produced by the diffractive optical element if it was illuminated with collimated light impinging perpendicular thereon.

If the diffractive optical element is rotated around two orthogonal axes, the above stated effect superimposes for the two directions, provided that the diffractive optical element alters the divergence in two orthogonal directions as well. If the diffractive optical element alters the divergence only in one direction, there is an axis of rotation for which rotations do not cause the above mentioned deformations of the illuminated field.

If the normal on the element plane extends in a plane containing a scan direction and the optical axis, this will result in a deformation along the scan direction, provided that the diffractive optical element alters the divergence in the scan direction. The larger the tilt angle α is in this case, the stronger will be the distortion.

If the diffractive optical element is configured such that it produces a rectangular light field in the far field if illuminated with collimated light impinging perpendicular thereon, rotating the element around an axis perpendicular both to the optical axis and the scan direction results in an illuminated field that has the shape of a ring segment.

The diffractive optical element may be a diffuser, for example realized as a hologram, and in particular as a computer generated hologram, as are known in the art as such.

If it is required that the shape of the illuminated field can be modified, for example if the illumination system shall be configured such that is can be used with different projection lenses, an actuator may alter the tilt angle α by exerting a torque on the diffractive optical element or a holder receiving the diffractive optical element.

### BRIEF DESCRIPTION OF THE DRAWINGS

Various features and advantages of the present invention may be more readily understood with reference to the following detailed description taken in conjunction with the accompanying drawing in which:

FIG. 1 is a perspective and simplified view of a projection exposure apparatus comprising an illumination system and a projection lens;

FIG. 2 is a simplified meridional section through the projection lens shown in FIG. 1;

FIG. 3 is a simplified meridional section through the illumination system shown in FIG. 1;

FIG. 4 is a top view of a diffractive optical element contained in the illumination system of FIG. 3;

FIG. 5 is an enlarged portion of FIG. 3 showing the diffractive optical element in more detail;

FIG. 6 shows the intensity distribution in the mask plane with a tilt angle α=0°;

FIG. 7 shows the intensity distribution in the mask plane with a tilt angle α=25°;

FIG. 8 shows an alternative embodiment in a representation similar to FIG. 5;

FIG. 9 shows a perspective view of a micro-lens array contained in the embodiment shown in FIG. 8.

### DESCRIPTION OF PREFERRED EMBODIMENTS

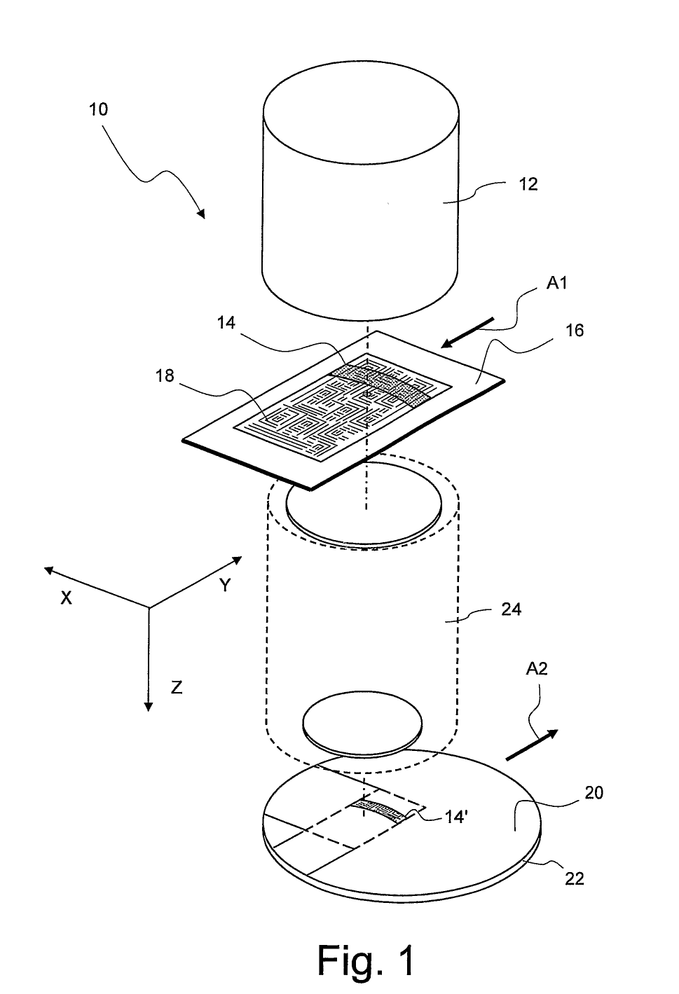

FIG. 1 shows a perspective and highly simplified view of an exemplary projection exposure apparatus according to the invention. The projection exposure apparatus, which is denoted in its entirety by 10, comprises an illumination system 12 that produces a projection light bundle. The projection light bundle illuminates a field 14 on a mask 16 containing minute structures 18. The illuminated field 14 has approximately the shape of a ring segment. To be more precise, straight lines form the boundaries of the illuminated field 14 along a Y-direction and segments of concentric circles along an X-direction.

A projection lens 24 images the structures 18 within the illuminated field 14 onto a light sensitive layer 20, for example a photoresist, which is deposited on a substrate 22. The substrate, which is realized in this embodiment as a silicon wafer, is arranged on a wafer stage (not shown) such that a top surface of the light sensitive layer 20 is precisely located in an image plane of the projection lens 24. The mask 16 is positioned by a mask stage (not shown) in an object plane of the projection lens 24. Since the latter has a magnification of less than 1, a minified image 14′ of the structures 18 within the illuminated field 14 is projected onto the light sensitive layer 20.

During the projection, the mask 16 and the substrate 22 move along a scan direction which coincides with the Y-direction. Thus the illuminated field 14 scans over the mask 16 so that structured areas larger than the illuminated field 14 can be continuously projected. Such a type of projection exposure apparatus is often referred to as “step-and-scan tool” or simply a “scanner”. The ratio between the velocities of the mask 16 and the substrate 22 is equal to the magnification of the projection lens 24. If the projection lens 24 inverts the image, the mask 16 and the substrate 22 move in opposite directions, as this is indicated in FIG. 1 by arrows A1 and A2.

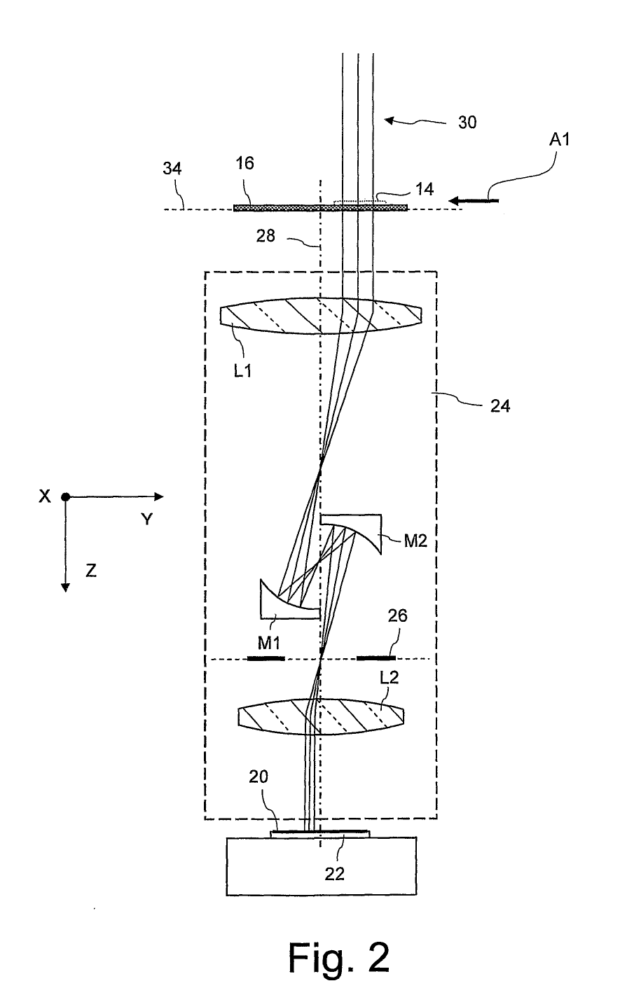

FIG. 2 shows a simplified meridional section through the projection lens 24 used in the projection exposure apparatus 10. In this simplified representation, the projection lens 24 comprises two lens elements L1, L2, two truncated concave mirrors M1, M2 and an aperture stop 26. These optical elements are aligned along a common optical axis 28. Reference numeral 30 denotes a bundle of principal rays that pass the illuminated field 14 on the mask 16 parallel to optical axis 28.

Due to the use of the truncated concave mirrors M1, M2, the illuminated field 14 on the mask 16 has to be positioned off the optical axis 28, i.e. the optical axis 28 does not intersect the illuminated field 14. It is further assumed that, for reasons of properly guiding the light rays within the projection lens 24, the mask 16 has to be illuminated by an off-axis illuminated field that has the form of a ring segment, as is shown in FIG. 1.

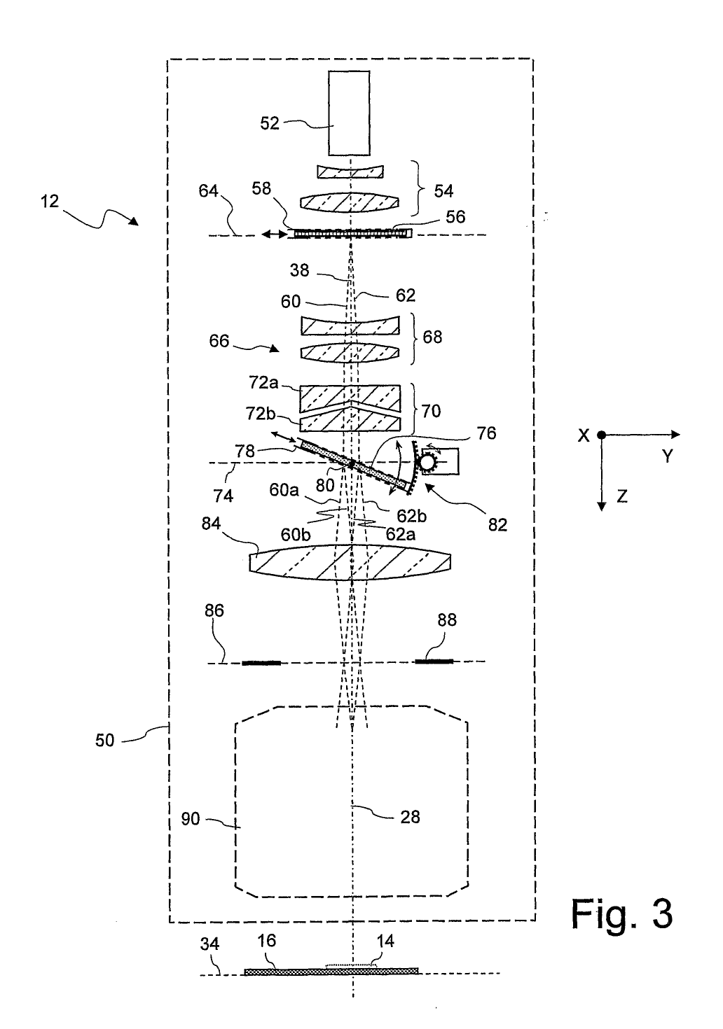

FIG. 3 is a more detailed meridional section through the illumination system 12 shown in FIG. 1. For the sake of clarity, also the illustration of FIG. 3 is considerably simplified and not to scale. This particularly implies that different optical units are represented by very few optical elements only. In reality, these units may comprise significantly more lenses and other optical elements.

The illumination system 12 comprises a housing 50 and a light source that is, in the embodiment shown, realized as an excimer laser 52. The excimer laser 52 emits projection light that has a wavelength in the deep ultraviolet (DUV) spectral range, for example 193 nm. Other wavelengths, for example 248 nm or 157 nm, are also contemplated.

The projection light emitted by the excimer laser 52 enters a beam expansion unit 54 in which the light bundle is expanded. After passing through the beam expansion unit 54, the projection light impinges on a first optical raster element 56. The first optical raster element 56 is received in a first exchange holder 58 so that it can easily be replaced by other optical raster elements having different properties. The first optical raster element 56 comprises, in the embodiment shown, one or more diffraction gratings that deflect each incident ray such that a divergence is introduced. This means that at each location on the optical raster element 56, light is diffracted within a certain range of angles. This range may extend, for example, from −3° to +3°. In FIG. 3 this is schematically represented for an axial ray that is split into two diverging rays 60, 62. The first optical raster element 56 thus modifies the angular distribution of the projection light and influences the local intensity distribution in a subsequent pupil plane. Other kinds of optical raster elements, for example micro-lens arrays, may be used instead or additionally.

The first optical raster element 56 is positioned in an object plane 64 of a first objective 66 that is indicated by a zoom lens group 68 and a pair 70 of axicon elements 72, 72 having opposing conical faces. If both axicon elements 72a, 72b are in contact, the axicon group has the effect of a plate having parallel plane surfaces. If both elements 72a, 72b are moved apart, the spacing between the axicon elements 72a, 72b results in a shift of light energy radially outward. Since axicon elements are known as such in the art, these will not be explained here in further detail.

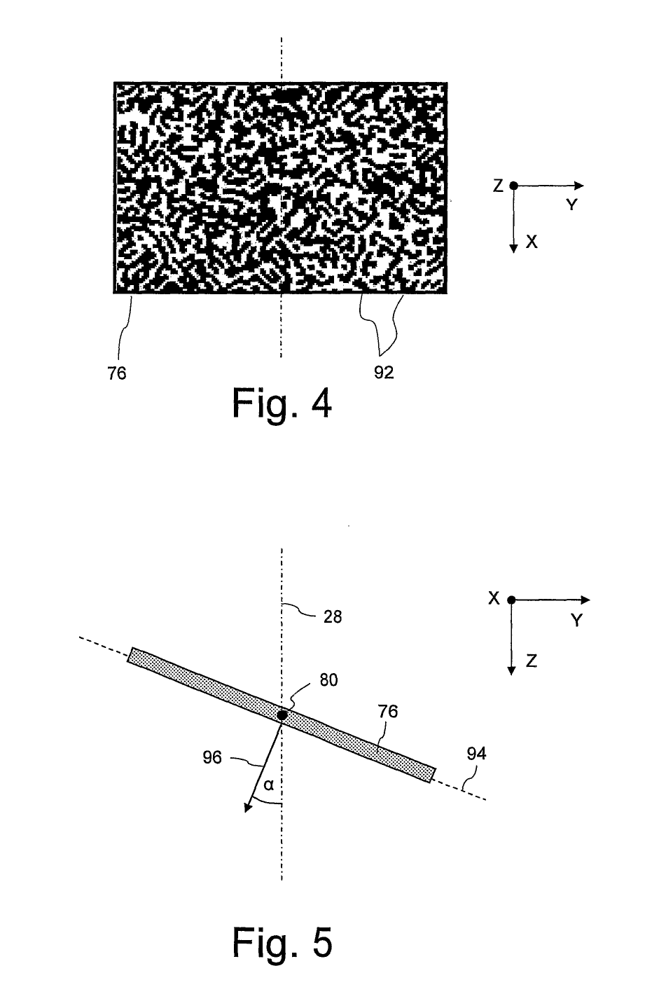

Reference numeral 74 denotes an exit pupil plane of the first objective 66. A diffractive optical element 76 realized as a computer generated hologram (CGH) is positioned in or in close proximity to the exit pupil plane 74 of the first objective 66. The diffractive optical element 76 introduces a divergence for each point and influences the geometry of the illuminated field 14 on the mask M. The divergence introduced by the diffractive optical element 76 is schematically represented in FIG. 3 by divergent rays 60a, 60b and 62a, 62b for the impinging rays 60 and 62. If the illuminated field 14 has the shape of a curved slit as is shown in FIG. 1, the exit side numerical aperture of the diffractive optical element 76 may be in the range from 0.28 to 0.35 in the X-direction and in the range from 0.07 to 0.09 in the Y-direction. Further details relating to the diffractive optical element 76 are discussed below with reference to FIG. 4.

The diffractive optical element 76 is received in a second exchange holder 78 that can be rotated around an axis of rotation 80 that is parallel to the X-direction. An actuator 82 is provided for tilting the exchange holder 78 around the axis of rotation 80. The actuator 82 may be realized by a micrometer adjustment device represented in FIG. 3 by a pinion drive. The micrometer adjustment device may be activated by a linear motor or manually using a micrometer screw, for example.

The diverging rays 60a, 60b and 62a, 62b emerging from the diffractive optical element 76 enter a second objective 84 that is represented in FIG. 3 by a single condenser lens. The second objective 84 is arranged within the illumination system 12 such that its entrance pupil plane coincides with the exit pupil plane 74 of the first objective 66. An image plane 86 of the second objective 84 is a field plane, close to which a field stop 88 is positioned. A field stop objective 90 images the field stop 88 onto the mask plane 34. The field stop ensures sharp edges of the illuminated field at least for the short lateral sides extending along the Y-direction.

FIG. 4 shows a top view of the diffractive optical element 76. The diffractive optical element 76 comprises a plurality of minute binary diffractive structures 92 that are lithographically defined on a flat optical substrate. The diffractive structures 92 are computationally determined such that, in the far field, a rectangular intensity distribution is obtained. This means that the numerical apertures NA in the X- and Y-direction are different, as has been explained above with reference to FIG. 2. Despite the use of the term “binary”, the resulting hologram does not have to consist of just 2 levels, but may comprise multiple phase levels that may be produced either by using multiple mask methods or by grayscale printing techniques. A diffractive optical element of this kind is often referred to as diffuser. The design and fabrication of binary optic diffusers are described in more detail in an essay of A. Fedor in Proc. SPIE Vol. 4557, p. 378-385, Micromachining and Microfabrication Process Technology VII.

FIG. 5 shows an enlarged view of the diffractive optical element 76, but without the exchange holder 78 and the actuator 82. The diffractive optical element 76 extends in an element plane 94 having a normal 96 that forms a tilt angle α≠0° with the optical axis 28. The tilt angle α may be altered by rotating the diffractive optical element 76 around the axis of rotation 80.

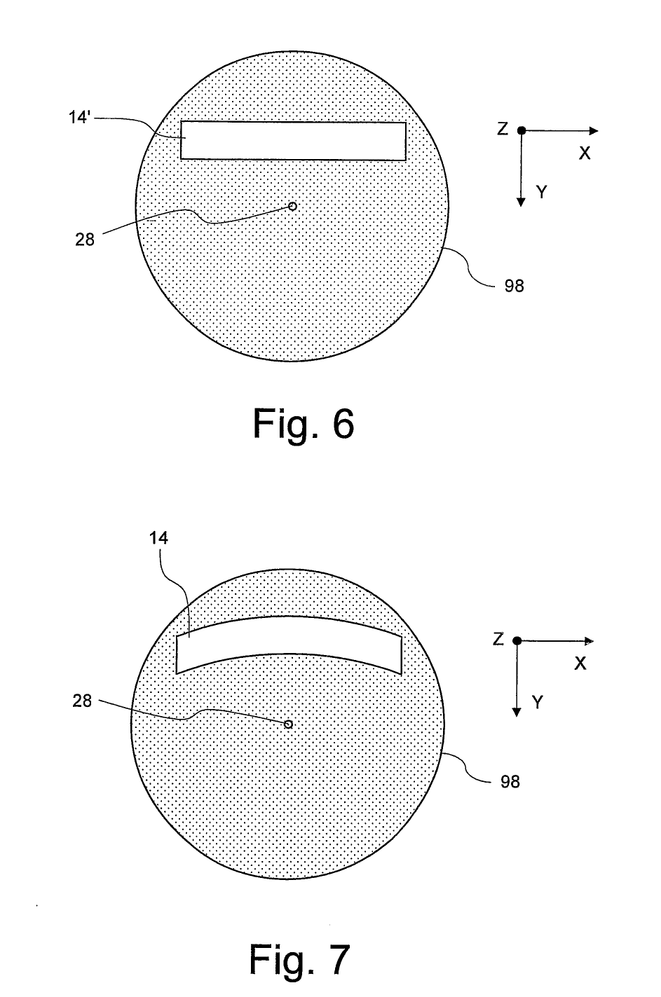

If α=0°, the element plane 94 of the diffractive optical element 76 extends perpendicular to the optical axis 28, as is the case in conventional illumination systems. Since the diffractive optical element 76 produces a rectangular light intensity distribution in the far field, if it is illuminated by collimated light impinging perpendicularly thereon, the illuminated field on the mask 16 has a rectangular shape as well. This is shown in FIG. 6, in which the rectangular illuminated field is denoted by 14′. The dotted area 98 indicates the region which would be illuminated by the illumination system 12 if the only limiting factor was the clear aperture of the optical elements contained in the illumination system 12.

As the tilt angle α is increased to a value α≠0° by rotating the diffractive optical element 76, the rectangular illuminated field 14′ starts bending along the Y-direction so that the curved geometry of a ring segment is obtained. This is shown in FIG. 7 for a tilt angle α≈25°. The curvature of the illuminated field 14 grows with increasing tilt angle α. By rotating the diffractive optical element 76 around the axis 80 it is thus possible to adjust the curvature of the illuminated field 14 along the Y-direction. This redistribution of the light in the mask plane 34 is achieved merely by redirecting the light energy at the diffractive optical element 76, but without readjusting the field stop 88. If the tilt angle α was fixed to 0°, the same effect could only be achieved if a large area on the field plane 86 would be illuminated such that the field stop 88 can “cut out” the desired shape of the illuminated field. This would unavoidably result in considerable light losses at the field stop 88.

The tilt angle α may thus be varied using the actuator 82 until the desired ring shape of the illuminated field 14 is achieved.

If the diffractive optical element 76 was rotated not around the axis 80 which is parallel to the X-direction, but around an axis parallel to the Y-direction, the illuminated field 14 would bend in the X-direction. In the present embodiment such a curvature would not be useful. However, there may be instances in which bending the illuminated field along the X-direction or even along both the X- and the Y-direction may be advantageous. In this context it has to be borne in mind that deviating from a perpendicular orientation of the diffractive optical element 76 with respect to the optical axis 28 introduces a distortion that may be used not only for causing a curvature, but also to reduce a curvature already present in an illuminated field obtained with perpendicular orientation.

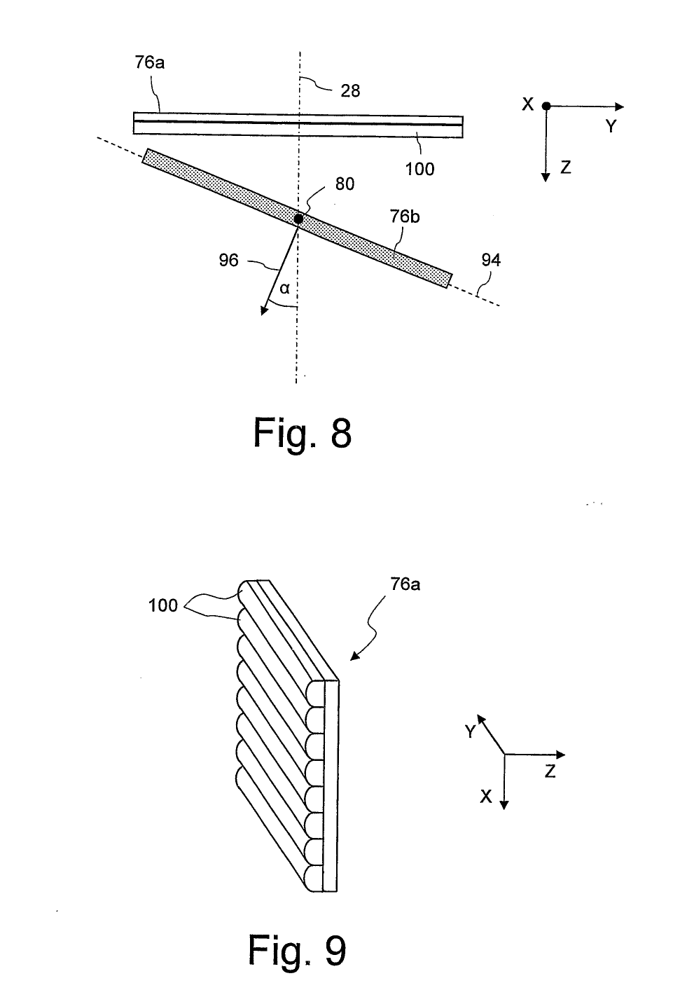

FIG. 8 shows an alternative embodiment in an illustration similar to FIG. 5. In this alternative embodiment the function of the diffractive optical element 76 is distributed among two distinct optical elements, namely a refractive optical element 76a and diffractive optical element 76b. The refractive optical element 76a increases the divergence of impinging light only in the X-direction, whereas the diffractive optical element 76b increases the divergence only in the Y-direction.

Since rotating a diffractive optical element around an axis of rotation locally varies the divergence only in a direction perpendicular to the axis of rotation, it is sufficient to rotate only the diffractive optical element 76b around the axis 80 if the intensity distribution shall be deformed solely along the Y direction. The refractive optical element 76a may still be arranged perpendicular to the optical axis 28.

Providing two distinct elements for increasing the divergence in two orthogonal directions allows to increase the efficiency, i.e. the proportion of light that is diverted into the desired direction. In the embodiment shown in FIG. 8, the refractive optical element 76a is realized as an array of parallel cylindrical micro-lenses 100. FIG. 9 shows a simplified perspective view of such an array. For the sake of simplicity the refractive optical element 76a is illustrated with a considerably reduced number of micro-lenses 100. This or similar refractive optical elements divert about 90% of the impinging light into the desired directions. In contrast, diffractive optical elements having a numerical aperture NA>0.3 can only be manufactured as two-level phase profiles having a diffraction efficiency of less than 80%.

The diffractive optical element 76b, however, may nevertheless be realized as a diffuser, as has been described above. This is due to the fact that the diffractive optical element 76b has to provide a numerical aperture NA that is much smaller, for example in the range between 0.07 and 0.09. As a result, it may be manufactured with a 4 or 8 level technology that allows diffraction efficiencies of more than 90%.

Thus the combination of a refractive optical element 76a having a large numerical aperture and a diffractive optical element 76b having a small numerical aperture allows to achieve efficiencies of more than 90% for diverting the light both in the X-direction and the Y-direction.

If the first optical raster element 56 is also realized as a diffractive optical element, it may also be arranged such that a normal on an element plane forms a tilt angle α′≠0° with the optical axis 28, similar to what has been explained above relating to the diffractive optical element 76. In such a configuration, the intensity distribution in the pupil plane 74 can be modified by rotating the first optical raster element 56, i.e. only by redirecting light and without using stops.

1. An optical system having an optical axis and a pupil plane, the optical system comprising:
a diffractive optical element that
i) is positioned at least approximately in the pupil plane and
ii) extends in an element plane whose normal is inclined with respect to the optical axis by a tilt angle α≠0°,
wherein the optical system is a microlithography projection exposure apparatus illumination system.

2. The optical system of claim 1, wherein the diffractive optical element is configured such that it increases the divergence of an impinging light bundle only along one direction.

3. The optical system of claim 2, wherein the one direction is a scan direction of the microlithographic projection exposure apparatus.

4. The optical system claim 3, wherein the normal of the element plane extends in a plane containing the scan direction and the optical axis.

5. The optical system of claim 1, wherein the diffractive optical element is configured such that it increases the divergence of an impinging light bundle in two orthogonal directions.

6. The optical system of claim 5, wherein the diffractive optical element is configured such that it produces a rectangular light field in the far field if illuminated with collimated light impinging perpendicular thereon.

7. The optical system of claim 5, wherein the illumination system produces in a mask plane, in which a mask is arranged during operation of the illumination system, an elongated light field having two opposing curved first boundaries extending substantially in a first direction and two opposing second boundaries that are shorter than the first boundaries and extend in a second direction that is perpendicular to the first direction.

8. The optical system of claim 7, wherein the second direction is a scan direction of the microlithographic projection exposure apparatus.

9. The optical system of claim 7, wherein the normal of the element plane extends in a plane containing the second direction and the optical axis.

10. The optical system of claim 1, wherein the diffractive optical element is a diffuser.

11. The optical system of claim 10, wherein the diffuser is a hologram.

12. The optical system of claim 11, wherein the hologram is a computer generated hologram.

13. The optical system of claim 10, wherein the diffuser is a two-level structure.

14. The optical system of claim 1, further comprising an actuator that changes the tilt angle α by exerting a torque on the diffractive optical element.

15. A system having an optical axis and a pupil plane, the optical system comprising:
a holder configured to receive a diffractive optical element, and
an actuator configured to rotate the holder around an axis of rotation that forms an angle β≠0° with the optical axis
wherein the optical system is a microlithography projection exposure apparatus illumination system.

16. The optical system of claim 15, wherein the angle β is 90°.

17. The optical system of claim 16, wherein the axis of rotation is perpendicular to the optical axis and to a scan direction of the microlithographic projection exposure apparatus.

18. A system, comprising:
a) an optical system according to claim 1,
b) a mask stage for positioning a mask in a mask plane, and
c) a projection lens that images the mask plane on an image plane,
wherein the system is a microlithography projection exposure apparatus.

19. A method, comprising:
a) providing a microlithography projection exposure apparatus an illumination system comprising an optical axis, a pupil plane and a diffractive optical element that is positioned at least approximately in the pupil plane and extends in an element plane;
b) changing an angle α formed between the optical axis and a normal on the element plane to change a curvature of an elongated light field produced in a mask plane by the illumination system.

20. A method, comprising:
a) providing a substrate supporting a light sensitive layer;
b) providing a mask containing structures to be imaged onto the light sensitive layer;
c) providing the system according to claim 18;
d) projecting at least a part of the mask onto the light sensitive layer.

21. The method according to claim 20, wherein the method fabricates a microstructured device.
